(19) United States
(12) Patent Application Publication
(10) Pub. No.: US 2026/0081594 A1
(43) Pub. Date: Mar. 19, 2026

(54) SEMICONDUCTOR DEVICE AND A PROPERTY MATCHING METHOD THEREOF

(71) Applicant: WHALECHIP CO., LTD., Taipei City (TW)

(72) Inventors: Chih-Hsin TSAI, Taipei City (TW); Huey-Jen LIM, Taipei City (TW)

(21) Appl. No.: 19/242,994

(22) Filed: Jun. 19, 2025

(30) Foreign Application Priority Data
Sep. 13, 2024 (CN) 2024112825206
Sep. 13, 2024 (CN) 2024112825282

(51) Int. Cl. H03K 17/16

(52) U.S. Cl. CPC H03K 17/162; H03K 2217/0027; H03K 2217/0036

(57) ABSTRACT

The disclosure is related to a semiconductor device and a property matching method thereof. The semiconductor device includes a frequency variable element, a matching control unit and a matching adjustment circuit. The matching control unit is connected to the frequency variable element to detect a noise voltage of the frequency variable element. The matching adjustment circuit is connected to the frequency variable element and the matching control unit. The matching control unit dynamically adjusts the property of the matching adjustment circuit based on the noise voltage of the frequency variable element to change the property of the semiconductor device accordingly.

### CROSS-REFERENCES

This application claims the priority benefit of Chinese Patent Application Serial Number 2024112825282, filed on Sep. 13, 2024, and Chinese Patent Application Serial Number 2024112825206, filed on Sep. 13, 2024, the full disclosures of which are incorporated herein by reference.

### TECHNICAL FIELD

The present disclosure relates to a semiconductor device, and more particularly to a semiconductor device packaged by an advanced packaging process and a property matching method thereof.

### DESCRIPTION OF RELATED ART

Common chip devices are usually packaged using a conventional IC (Integrated Circuit) standard packaging process. Through processes such as bonding, wire bonding, and molding, the die is packaged into an existing chip device, which is arranged on a circuit board so as to operate together with other electronic devices through the circuits of the circuit board. Generally, in order to ensure the stability of the overall circuit, a chip device and a circuit board whose zeros and poles are matched to each other are selected. However, due to the influence of the process and/or the operating state of the chip device, the zeros and poles of the chip device and the circuit board cannot be completely matched. Furthermore, the zero and pole of the chip device may shift with different operating conditions. This results in a large difference in the zeros and poles between the chip device and the circuit board, and the overall circuit has poor stability.

Therefore, in order to improve the performance of chip devices without increasing their size, an advanced packaging process that can integrate dies of different processes and properties has been proposed. The CoWoS (Chip-on-Wafer-on-Substrate) process is one of the most popular advanced packaging processes. The CoWoS process is a packaging process that stacks chips and then packages them on a substrate. Multiple dies are arranged or stacked on the substrate, and multiple dies can be electrically connected through an interposer or silicon vias in the dies. Thereby, the size of the chip device can be greatly reduced, and the CoWoS process has the advantages of reducing the power consumption and cost.

Therefore, existing devices and systems have considerable requirements for optimizing the zero-pole matching between a die and a substrate based on the CoWoS process.

### SUMMARY OF THE INVENTION

The embodiment of the present disclosure provides a semiconductor device and a property matching method for dynamically adjusting a property of the semiconductor device such that the semiconductor device may dynamically match a zero and pole of a frequency variable element in response to an operating state of the frequency variable element. Thus, the effect of improving a circuit stability of the semiconductor device is achieved.

In order to achieve the above object and other related objects, the present disclosure provides a semiconductor device, which includes a frequency variable element, a matching control unit and a matching adjustment circuit. The matching control unit is connected to the frequency variable element for detecting a noise voltage of the frequency variable element. The matching adjustment circuit is connected to the frequency variable element and the matching control unit. The matching control unit dynamically adjusts the matching adjustment circuit based on the noise voltage of the frequency variable element to change a property of the semiconductor device.

In order to achieve the above object and other related objects, the present disclosure provides a property matching method of a semiconductor device, which is applicable to the semiconductor device as described above and includes the following steps: obtaining a noise voltage, and dynamically adjusting a property of the matching adjustment circuit for changing the property of the semiconductor device, based on the noise voltage.

According to above, through the semiconductor device and the property matching method of the present application, the noise voltage of the frequency variable element may be monitored in real time, and the adjustment of the matching adjustment circuit is determined based on the noise voltage. Thereby, the property of the semiconductor device may be changed, and the zero and pole of the semiconductor device may be dynamically matched with the zero and pole of the frequency variable element corresponding to the operating condition of the frequency variable element. The effect of improving a circuit stability of the semiconductor device is achieved.

### BRIEF DESCRIPTION OF DRAWINGS

FIG. 1 is a schematic of a semiconductor device according to an embodiment of the present disclosure.

FIG. 2 is a schematic of a circuit block of the semiconductor device according to an embodiment of the present disclosure.

FIG. 3 is a schematic of a configuration of a frequency variable element according to an embodiment of the present disclosure.

FIG. 4 is a schematic of a matching adjustment circuit according to an embodiment of the present disclosure.

FIG. 5 is a schematic of a matching adjustment circuit according to another embodiment of the present disclosure.

FIG. 6 is a schematic of a matching adjustment circuit according to another embodiment of the present disclosure.

FIG. 7 is a schematic of a capacitor component according to an embodiment of the present disclosure.

FIG. 8 is a schematic of a variation of a unit capacitance value of the capacitor component according to an embodiment of the present disclosure.

FIG. 9 is a schematic of a property matching method according to an embodiment of the present disclosure.

### DESCRIPTION OF THE INVENTION

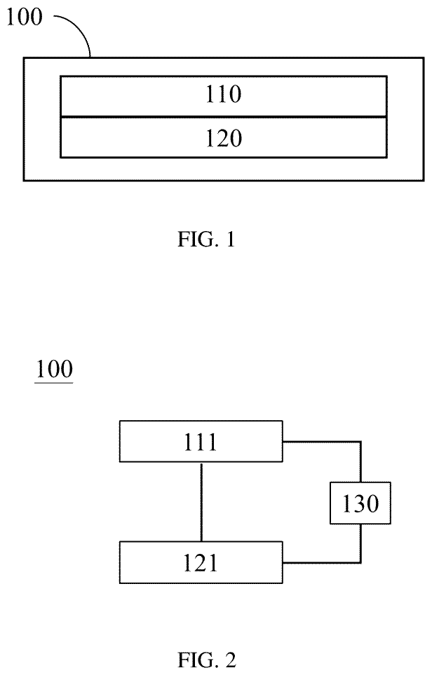

Please refer to FIG. 1. FIG. 1 is a schematic of a semiconductor device according to an embodiment of the present disclosure. The semiconductor device 100 includes an electronic component layer 110 and a carrying layer 120. The electronic component layer 110 includes a plurality of electronic components. The electronic component layer 110 is disposed on the carrying layer 120. The carrying layer 120 is electrically connected to the electronic component layer 110. In the embodiment, the semiconductor device 100 is a semiconductor device packaged using a CoWoS (Chip on Wafer on Substrate with silicon interposer) process. The electronic component layer 110 and the carrying layer 120 may be realized through a semiconductor process and stacked before packaging. In one embodiment, the electronic component is, for example, a die component for implementing a system on a chip (SoC) or a high bandwidth memory (HBM), and the present disclosure is not limited thereto. In one embodiment, the carrying layer 120 includes a silicon interposer layer, a bridge die layer, a local silicon interconnect (LSI) layer, a redistribution layer (RDL), a semiconductor layer, a packaging layer, a board bonding layer and/or a bonding layer. The carrying layer 120 may be electrically connected to the electronic component layer 110 directly or indirectly. For example, in an embodiment where the carrying layer 120 is a redistribution layer, a silicon interposer, a bridge die layer and/or a local silicon interconnect layer may be provided between the carrying layer 120 and the electronic component layer 110. Thus, the carrying layer 120 may be electrically connected to the electronic component layer 110 through the silicon interposer, the bridge die layer and/or the local silicon interconnect layer, and the present disclosure is not limited thereto.

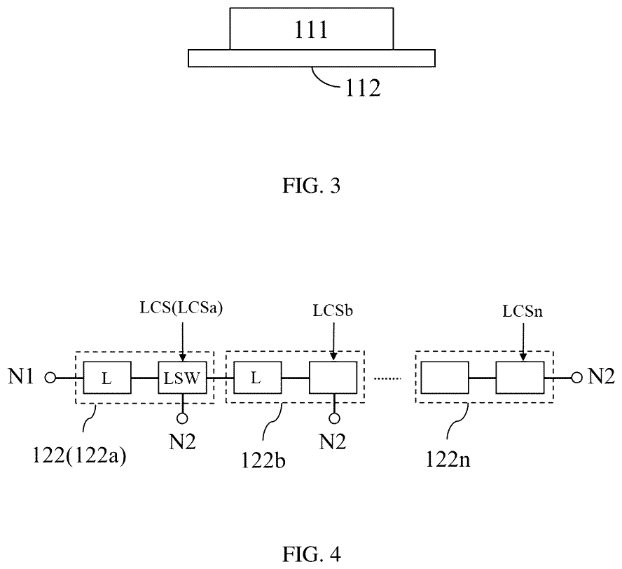

Please refer to FIG. 2 and FIG. 3. FIG. 2 is a schematic of a circuit block of the semiconductor device according to an embodiment of the present disclosure. FIG. 3 is a schematic of a configuration of a frequency variable element according to an embodiment of the present disclosure. The semiconductor device 100 includes a frequency variable element 111, a matching control unit 130 and a matching adjustment circuit 121.

The frequency variable element 111 is disposed on the electronic component layer 110. A frequency of the frequency variable element 111 is changed with different operating conditions. For example, the frequency variable element 111 may operate in different operating conditions, such as an overclocking state, a high frequency state, or a low frequency state, and the present disclosure is not limited thereto. In one embodiment, the frequency variable element 111 is a frequency-generating element such as a computing element (for example, a microprocessor component, a microcontroller component, a digital signal processor component, etc.), a power processing circuit element (for example, a buck converter, a filter component, a rectifier circuit component, etc.), a signal transmitting element (for example, a transceiver), a switching element, etc. The frequency generated includes, for example, a fixed frequency, a non-fixed frequency, a variable frequency, an adjustable frequency, and all electrical frequencies generated, and the present disclosure is not limited thereto. The frequency variable element 111 is disposed on a substrate 112. The substrate 112 is used to carry the frequency variable element 111. The substrate 112 is connected to the frequency variable element 111.

The matching adjustment circuit 121 is connected to the frequency variable element 111 and the matching control unit 130. A property of the matching adjustment circuit 121 is adjustable. In the embodiment, the property is an inductance value or a capacitance value. In the embodiment, the matching adjustment circuit 121 is disposed in the substrate 112, and the matching adjustment circuit 121 is disposed in the electronic component layer 110 or the carrying layer 120. In the embodiment, the substrate 112 includes an electronic component layer 110 including the matching adjustment circuit 121 or a carrying layer 120. For example, when the matching adjustment circuit 121 is disposed in the electronic component layer 110, the substrate 112 includes one or more layers disposed in the electronic component layer, and one or more layers include the matching adjustment circuit 121 and carry the frequency variable element 111. That is, the substrate 112 may include one or more layers between the frequency variable element 111 and the matching adjustment circuit 121 and a layer having the matching adjustment circuit 121. For example, when the matching adjustment circuit 121 is disposed in the carrying layer 120, the substrate 112 includes a layer in the carrying layer 120 in which the matching adjustment circuit 121 is disposed and one or more layers in the carrying layer 120 and the electronic component layer 110 in which the frequency variable element 111 is carried.

The matching control unit 130 is connected to the frequency variable element 111 and the matching adjustment circuit 121. The matching control unit 130 is used to detect the noise voltage of the frequency variable element 111 in real time and to determine whether to generate a control signal based on the noise voltage of the frequency variable element 111. The matching control unit 130 adjusts the property of the matching adjustment circuit 121 through the control signal. Thereby, the zero and pole of the substrate 112 are matched with the zero and pole of the frequency variable element 111. In the embodiment, the matching control unit 130 may be implemented by at least a conventional noise detection circuit or a microcontroller element, and the present disclosure is not limited thereto. In the embodiment, the matching control unit 130 may be disposed in the electronic component layer 110, the carrying layer 120, or other intermediate layers electrically connected to the electronic component layer 110 and the carrying layer 120, and the present disclosure is not limited thereto. In one embodiment, the matching control unit 130 may also be implemented by a frequency variable element 111, and the present disclosure is not limited thereto.

Since the frequency variable element 111 operates in different operating conditions, the zero and pole of the frequency variable element 111 change with the operating conditions. Therefore, the zero and pole of the frequency variable element 111 and the substrate 112 may not be maintained in a matching state. When the difference between the zero and pole of the substrate 112 and the zero and pole of the frequency variable element 111 is larger, the noise voltage of the frequency variable element 111 increases accordingly. For example, the noise voltage of a bump connecting the frequency variable element 111 to the substrate 112 is increased. Therefore, the present disclosure may quickly and easily confirm a matching state of the zeros and poles between the substrate 112 and the frequency variable element 111 by detecting the noise voltage. In addition, based on the operating condition of the frequency variable element 111, when the difference between the zero and pole of the substrate 112 and the zero and pole of the frequency variable element 111 is too large, the matching control unit 130 may change the property (the capacitance value or the inductance value) of the matching adjustment circuit 121. Therefore, the zero and pole of the substrate 112 as a whole may be changed accordingly to reduce the noise voltage of the frequency variable element 111. Thereby, the zero and pole of the substrate 112 are matched with the zero and pole of the frequency variable element 111.

In one embodiment, the matching control unit 130 may determine whether the zero and pole of the substrate 112 match the zero and pole of the frequency variable element 111 by determining whether the noise voltage of the frequency variable element 111 is equal to or less than a threshold value. In one embodiment, since the zero and pole of the frequency variable element 111 are different when operating in different operating conditions, the matching control unit 130 may determine the threshold value by determining the operating condition of the frequency variable element 111. The threshold values corresponding to different zeros and poles are the same or different. In another embodiment, the matching control unit 130 may dynamically adjust the property of the matching adjustment circuit 121 and record the change of the noise voltage in real time until a minimum noise voltage is found and then stop adjusting the property of the matching adjustment circuit 121. In the embodiment, the minimum noise voltage represents that the zero and pole of the substrate 112 as a whole are the zero and pole that best match the frequency variable element 111. In one embodiment, the matching control unit 130 may determine whether to detect the noise voltage by determining whether the operating condition of the frequency variable element 111 changes. For example, when the matching control unit 130 determines that the frequency variable element 111 is converted from a high frequency state to a low frequency state, the matching control unit 130 detects the noise voltage. Thereby, it is possible to avoid the matching control unit 130 being in the state of detecting the noise voltage for a long time, and thereby, the overall power consumption of the semiconductor device 100 is reduced.

Please refer to FIG. 4. FIG. 4 is a schematic of a matching adjustment circuit 121 according to an embodiment of the present disclosure. The matching adjustment circuit 121 includes a plurality of inductor components 122 (122a to 122n) connected in series. Each of the inductor components 122 receives a control signal LCS (LCSa to LCSn) from the matching control unit 130 individually. Each of the inductor components 122 determines whether to connect to the frequency variable element 111 according to the received control signal LCS. One end of one of the plurality of inductor components 122 is connected to a terminal N1. Each of the inductor components 122 includes a switching unit LSW and an inductor unit L. The switching unit LSW is connected to the inductor unit L in series. The switching unit LSW determines whether to establish a connection with a terminal N2 or another inductor unit L according to the received control signal LCS. For example, the switching unit LSW of the inductor component 122a determines whether to establish a connection with the terminal N2 or with the inductor unit L of the inductor component 122b according to the control signal LCSa. In the embodiment, the terminal N1 is electrically connected to the frequency variable element 111, and the terminal N2 is grounded. In the embodiment, the switching unit LSW and the inductor unit L are a semiconductor switching unit and a semiconductor inductor unit formed in the carrying layer 120 through a semiconductor process. Thereby, the matching control unit 130 may determine the number of the inductor components 122 connected in series by the control signal LCS, thereby increasing or decreasing the inductance value of the matching adjustment circuit 121.

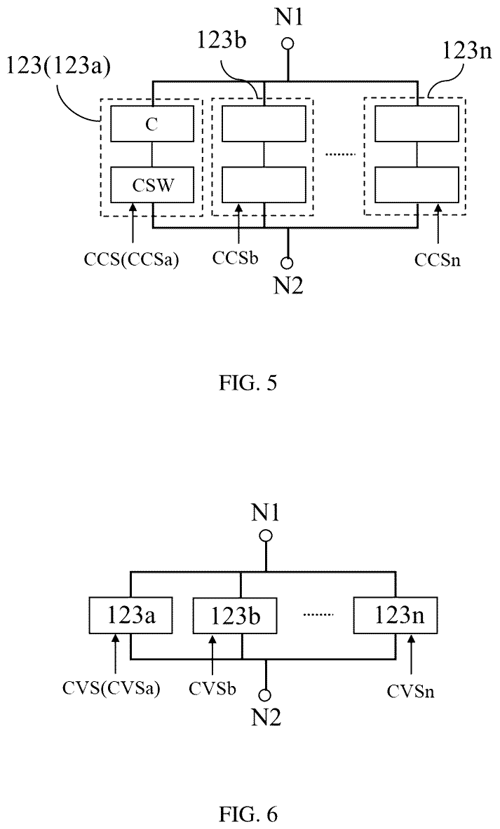

Please refer to FIG. 5. FIG. 5 is a schematic of a matching adjustment circuit according to another embodiment of the present disclosure. The matching adjustment circuit 121 includes a plurality of capacitor components 123 (123a to 123n) connected in parallel to each other. Each capacitor component 123 receives a control signal CCS (CCSa to CCSn) from the matching control unit 130 individually. Each of the capacitor components 123 determines whether to be connected to the frequency variable element 111 according to the received control signal CCS. One end of each of the capacitor components 123 is connected to the terminal N1, and the other end is connected to the terminal N2. Each of the capacitor components 123 includes a switching unit CSW and a capacitor unit C. The switching unit CSW is connected in series with the capacitor unit C. The switching unit CSW determines whether to establish a connection with the capacitor unit C according to the received control signal CCS. For example, the switching unit CSW of the capacitor component 123a determines whether to establish a connection with the capacitor unit C of the capacitor component 123a according to the control signal CCSa. In the embodiment, the terminal N1 is electrically connected to the frequency variable element 111, and the terminal N2 is grounded. In the embodiment, the switching unit CSW and the capacitor unit L are a semiconductor switching unit and a semiconductor capacitor unit formed in the carrying layer 120 through a semiconductor process. Thereby, the matching control unit 130 may determine the number of the capacitor components 123 connected in parallel by the control signal CCS, thereby increasing or decreasing the capacitance value of the matching adjustment circuit 121.

Please refer to FIG. 6. FIG. 6 is a schematic of a matching adjustment circuit according to another embodiment of the present disclosure. The matching adjustment circuit 121 includes a plurality of capacitor components 123 (123a to 123n) connected in parallel to each other. Each of the capacitor components 123 receives a bias control signal CVS (CVSa to CVSn) from the matching control unit 130. Each capacitor component 123 determines its capacitance value according to the received bias control signal CVS. One end of each capacitor component 123 is connected to the terminal N1, and the other end is connected to the terminal N2. In the embodiment, the capacitor component 123 is a Metal-Oxide-Semiconductor (MOS) Capacitor (MOSCAP). Thereby, the matching control unit 130 may determine the capacitance value of the parallel capacitor components 123 by the bias control signal CVS and further increase or decrease the capacitance value of the matching adjustment circuit 121.

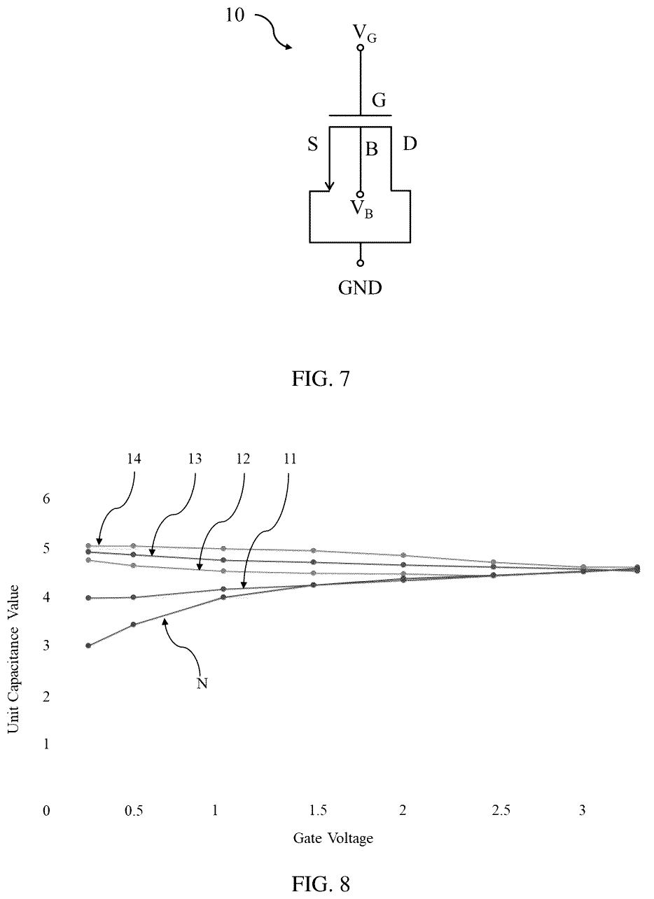

Please refer to FIG. 7. FIG. 7 is a schematic of a MOSCAP component according to an embodiment of the present disclosure. The MOSCAP component 10 has a gate terminal G, a source terminal S, a drain terminal D and a body terminal B. The gate terminal G is used to receive a gate voltage VG. The source terminal S is used for receiving a ground voltage GND. The drain terminal D is electrically connected to the source terminal S and receives a ground voltage GND. The base terminal B receives a control voltage VB, and the control voltage VB is different from a ground voltage GND. The control voltage VB may be implemented by the bias control signal CVS mentioned above. The MOSCAP component 10 may be used to implement the capacitor component 123 mentioned above. In the embodiment, the MOSCAP component 10 may be implemented by an N-type transistor, and the present disclosure is not limited thereto.

Therefore, unlike the conventional MOSCAP, the base terminal B of the MOSCAP component 10 of the present disclosure is not grounded, and the base terminal B of the MOSCAP component 10 of the present disclosure is used to receive the control voltage VB. Thus, a threshold voltage (or a critical voltage) of the MOSCAP component 10 may change in response to the control voltage VB. The capacitance value of the MOSCAP component 10 changes in response to the threshold voltage. That is, the capacitance value of the MOSCAP component 10 may be changed in response to the control voltage VB. The MOSCAP component 10 of the present disclosure may further adjust its capacitance value by adjusting the control voltage VB received by the base terminal B. Therefore, the MOSCAP component 10 may have a stable capacitance value without being affected by process deviation and operating temperature; thereby, the effect of making the circuit have better stability is achieved.

Please refer to FIG. 8. FIG. 8 is a schematic of a variation of a unit capacitance value of the MOSCAP component 10 embodiment of the present disclosure and a conventional MOSCAP under different gate voltages VG. The unit of the gate voltage VG is voltage (V), and the unit of the unit capacitance value is nF/mm². A reference N represents the variation of the unit capacitance value of a conventional MOSCAP. A reference 11 represents the variation of the unit capacitance value of the MOSCAP component 10 when the control voltage VB is 1V. A reference 12 represents the variation of the unit capacitance value of the MOSCAP component 10 when the control voltage VB is 2V. A reference 13 represents the variation of the unit capacitance value of the MOSCAP component 10 when the control voltage VB is 3V. A reference 14 represents the variation of the unit capacitance value of the MOSCAP component 10 when the control voltage VB is 3.3V. In FIG. 8, compared with the conventional MOSCAP, the MOSCAP component 10 of the present disclosure has different capacitance values due to the received different control voltages VB. Also, the MOSCAP component 10 of the present disclosure has a more stable capacitance value than the conventional MOSCAP under different gate voltages VG. Therefore, the MOSCAP component 10 of the present disclosure may have a stable capacitance value without being affected by process deviation and operating temperature; thereby, the effect of improving a circuit stability of the semiconductor device is achieved.

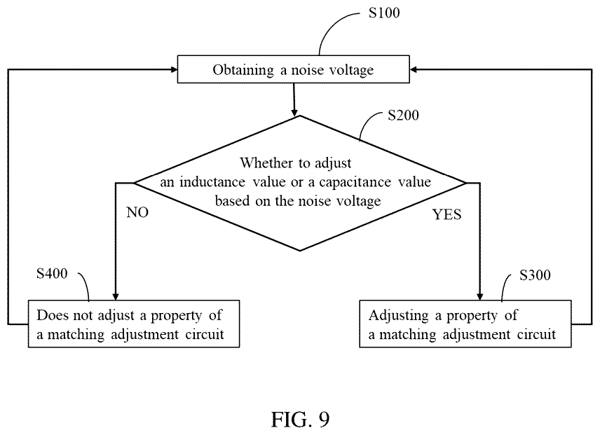

Please refer to FIG. 9. FIG. 9 is a schematic of a property matching method of the present disclosure, which may be implemented by the aforementioned semiconductor device 100, and the steps include S100-S400.

In step S100, a noise voltage is obtained. In this step, the matching control unit 130 detects the noise voltage of the frequency variable element 111 to confirm the current noise voltage of the frequency variable element 111. In one embodiment, the matching control unit 130 may further read an operating frequency of the frequency variable element 111.

In step S200, the matching control unit 130 determines whether to adjust the inductance value or the capacitance value of the matching adjustment circuit 121 based on the noise voltage. In one embodiment, when the matching control unit 130 determines that the noise voltage is greater than a threshold value, the matching control unit 130 adjusts the property of the matching adjustment circuit 121. In one embodiment, the matching control unit 130 may dynamically adjust the property of the matching adjustment circuit 121 and record the change of the noise voltage in real time until a minimum noise voltage is found. After the minimum noise voltage is found, the matching control unit 130 stops adjusting the property of the matching adjustment circuit 121. In one embodiment, the matching control unit 130 may determine whether to detect the noise voltage by determining whether the operating condition of the frequency variable element 111 changes. For example, when the matching control unit 130 determines that the frequency variable element 111 is converted from a high frequency state to a low frequency state, then the matching control unit 130 detects the noise voltage. When the matching control unit 130 determines to adjust the property of the matching adjustment circuit 121, the process continues to step S300. When the matching control unit 130 determines not to adjust the property of the matching adjustment circuit 121, the process continues to step S400.

In step S300, the matching control unit 130 adjusts the inductance value or the capacitance value of the matching adjustment circuit 121. In step S400, the matching control unit 130 does not adjust the inductance value or the capacitance value of the matching adjustment circuit 121, so the inductance value or the capacitance value of the matching adjustment circuit 121 remains unchanged. The process continues to step S100 after step S300 or step S400.

Thus, the property matching method of the present disclosure may obtain the desired noise voltage by adjusting the property of the matching adjustment circuit 121, thereby matching the zero and pole of the substrate 112 with the frequency variable element 111; thereby, the effect of improving a circuit stability of the semiconductor device is achieved.

According to the above, the semiconductor device and the property matching method of the present disclosure utilize advanced processes to enable the matching adjustment circuit to be set in the substrate before packaging through an advanced process. The present disclosure also uses a matching control unit to adjust the property of the matching adjustment circuit such that the property of the substrate may be dynamically adjusted. The zero and pole of the substrate may correspond to the operating condition of the frequency variable element and match the zero and pole of the frequency variable element. Thereby, the effect of improving a circuit stability of the semiconductor device is achieved.

1. A semiconductor device, comprising:
a frequency variable element;
a matching control unit, connected to the frequency variable element, configured to detect a noise voltage of the frequency variable element;
a matching adjustment circuit, connected to the frequency variable element and the matching control unit;
wherein the matching control unit is configured to dynamically adjust a property of the matching adjustment circuit based on the noise voltage of the frequency variable element for changing a property of the semiconductor device.

2. The semiconductor device as claimed in claim 1, wherein the property of the semiconductor device is an inductance value or a capacitance value.

3. The semiconductor device as claimed in claim 1, wherein the matching adjustment circuit comprises a plurality of inductor components connected in series, each of the inductor components receives a control signal from the matching control unit individually, and each of the inductor components determines whether to connect to the frequency variable element according to the received control signal.

4. The semiconductor device as claimed in claim 1, wherein the matching adjustment circuit comprises a plurality of capacitor components connected in parallel, each of the capacitor components receives a control signal from the matching control unit, and each of the capacitor components determines whether to connect to the frequency variable element according to the received control signal.

5. The semiconductor device as claimed in claim 4, wherein the capacitor component comprises a switching unit and a capacitor unit, the switching unit is connected in series with the capacitor unit, and the switching unit is configured to receive the control signal from the matching control unit.

6. The semiconductor device as claimed in claim 4, wherein the capacitor component is a metal-oxide-semiconductor capacitor.

7. The semiconductor device as claimed in claim 6, wherein the capacitor component is an n-type transistor.

8. The semiconductor device as claimed in claim 6, the capacitor component comprising:
a gate terminal, configured to receive a gate voltage;
a source terminal, configured to receive a ground voltage;
a drain terminal, electrically connected to the source terminal, configured to receive the ground voltage; and
a base terminal, configured to receive the control signal from the matching control unit;
wherein a voltage of the control signal is different to a voltage of the ground voltage and a capacitance value of the capacitor component is changed corresponding to the control signal.

9. The semiconductor device as claimed in claim 8, wherein a threshold voltage of the capacitor component changes in response to the control signal.

10. The semiconductor device as claimed in claim 1, wherein the semiconductor device further comprises an electronic component layer and a carrying layer, the electronic component layer is disposed on the carrying layer, and the matching adjustment circuit is configured on the electronic component layer or the carrying layer.

11. The semiconductor device as claimed in claim 1, wherein the semiconductor device is packaged using a chip on wafer on substrate with silicon interposer technology.

12. A property matching method of a semiconductor device, wherein the semiconductor device comprises a frequency variable element, a matching control unit and a matching adjustment circuit, and the matching control unit connects to the frequency variable element and the matching adjustment circuit, the property matching method comprising:
obtaining a noise voltage of the frequency variable element, by the matching control unit; and
dynamically adjusting the property of the matching adjustment circuit for changing the property of the semiconductor device, based on the noise voltage, by the matching control unit.

13. The property matching method as claimed in claim 12, further comprising:
adjusting an inductance value or a capacitance value of the matching adjustment circuit to increase or decrease an inductance value or a capacitance value of the semiconductor device.
